(19) United States
(12) Patent Application Publication
(10) Pub. No.: US 2023/0100829 A1
(43) Pub. Date: Mar. 30, 2023

(54) Circuit Systems And Methods Using Spacer Dies

(71) Applicant: Intel Corporation, Santa Clara, CA (US)

(72) Inventors: Sheue Fen Yong, Singapore (SG); Archanna Srinivasan, San Jose, CA (US); Graham Baker, Morgan Hill, CA (US); Pheak Ti Teh, Tanjung Bungah (MY)

(73) Assignee: Intel Corporation, Santa Clara, CA (US)

(21) Appl. No.: 18/070,361

(22) Filed: Nov. 28, 2022

(51) Int. Cl. H01L 25/065; H01L 23/00; H01L 23/538; H01L 25/00

(52) U.S. Cl. CPC H01L 25/0655; H01L 23/5381; H01L 24/16; H01L 25/50; H01L 2224/16221; H01L 2924/1431; H01L 2924/1433; H01L 2924/1435; H01L 2924/14335

(57) ABSTRACT

An integrated circuit package includes a first integrated circuit die, a spacer die coupled in the integrated circuit package in a location designed to house a second integrated circuit die, and a package substrate coupled to the first integrated circuit die and to the spacer die.

### FIELD OF THE DISCLOSURE

The present disclosure relates to electronic circuit systems, and more particularly, to circuit systems and methods using spacer dies to replace integrated circuit dies.

### BACKGROUND

Many modem electronic circuit systems include integrated circuit (IC) packages. An integrated circuit (IC) package may contain multiple integrated circuit dies. The integrated circuit dies in an IC package may, for example, be coupled together through an interposer, an interconnection bridge, conductive bumps, and/or a package substrate.

Programmable logic integrated circuits are a type of integrated circuit that can be programmed by a user to implement desired custom logic functions. In a typical scenario, a logic designer uses computer-aided design tools to design a custom logic circuit. When the design process is complete, the computer-aided design tools generate configuration data. The configuration data is loaded into memory elements in a programmable logic integrated circuit to configure the programmable logic integrated circuit to perform the functions of the custom logic circuit.

### BRIEF DESCRIPTION OF THE DRAWINGS

FIG. 1 is a diagram that illustrates a top down view of an example of an integrated circuit (IC) package that includes a package substrate, a spacer die, a main integrated circuit (IC) die, and an additional IC die.

FIG. 2 is a diagram that illustrates a cross sectional view of the integrated circuit (IC) package of FIG. 1.

FIG. 3 is a diagram that illustrates a top down view of an example of an integrated circuit (IC) package that includes a package substrate, a main integrated circuit (IC) die, two additional IC dies, and two spacer dies.

FIG. 4 is a diagram that illustrates a top down view of an example of an integrated circuit (IC) package that includes a package substrate, 6 IC dies that contain active circuitry, and two spacer dies.

FIG. 5 is a diagram of an illustrative programmable (i.e., configurable) logic integrated circuit (IC) that can be programmed according to a user design.

### DETAILED DESCRIPTION

An integrated circuit (IC) in an IC package can exchange information with external devices that are inside and outside the IC package using one or more high speed data transmission protocols. An IC package may also be referred to herein simply as a package. In some electronic circuit systems, the physical layer of a high speed data transmission protocol is implemented using circuitry in two or more integrated circuits that are housed in the same package. As an example, the physical layer of a data transmission protocol can be implemented in part by circuitry in a processing integrated circuit (IC) (such as a programmable logic IC, a microprocessor IC, or a graphics processing unit IC) and in part by circuitry in one or more transceiver integrated circuits (ICs) that are in the same package as the processing IC. The processing IC can include an interface that is designed to communicate with the transceiver IC and to implement the high speed data transmission protocol. A field programmable gate array (FPGA) is an example of a programmable logic IC.

Some electronic circuit systems include multiple integrated circuits (ICs) that perform processing functions in the same package. As an example, two, three, four, or more processing ICs can be housed in the same package. Each of the processing ICs in the package implements a data transmission protocol designed to communicate with the one or more other processing ICs in the same package. The integrated circuits in the package can, for example, be coupled together through a package substrate or interposer in the package. As another example, two integrated circuits can be stacked vertically and coupled together in a 3-dimensional (3D) arrangement.

A single integrated circuit (IC) package can be designed to house a processing IC and multiple transceiver ICs that implement a data transmission protocol for communications between the processing IC and one or more devices external to the IC package. Some applications for an IC package designed to house multiple transceiver ICs do not use all of the transceiver ICs in the package. In these applications, the unused transceiver ICs can be grounded or tied-off in the IC package. However, the unused transceiver ICs in the IC package consume leakage power and add unnecessary cost to the IC package, because all of the transceiver ICs are placed in the package, even if some of the transceiver ICs are not used by the application. Simply removing one or more unused transceiver ICs from an IC package can reduce the conductivity between the thermal interface material (TIM) in the package and the package substrate, which can undesirably reduce the effective heat dissipation in the IC package.

Designing a new IC package for each application that uses a different number of transceiver ICs in the package may require a substantial amount of additional engineering effort, cost, and time to design and test each new IC package. Thus, whenever a request is made to design a new custom-made IC package housing a different number of transceiver ICs, additional time and cost are required to modify the IC package, and the release date of the IC package may be substantially delayed. In addition, custom-made IC packages that are designed for unique applications may be over-built, because it is often difficult to estimate future demand for custom-made IC packages. As a result, many custom-made IC packages that are built may end up being unused. Also, custom-made IC packages are typically not scalable or reusable.

According to some examples disclosed herein, an integrated circuit (IC) package includes an IC die and a spacer die that replaces a second unused IC die (e.g., a transceiver IC die) in the IC package. The spacer die can be, for example, a dummy die that does not have any passive or active circuitry. The IC package can include multiple spacer dies that replace multiple unused IC dies. The IC package can also include other IC dies that contain active circuitry. Because one or more IC dies in the IC package can be replaced with one or more spacer dies, the design of the IC package can be reused for many different applications. The spacer dies can be, for example, open circuit short-loop dies that are made from semiconductor wafers that are created as part of transceiver IC dies power-on readiness.

The spacer dies do not require additional research and development to design and test. Therefore, the spacer dies typically cost substantially less than IC dies that include active circuitry (e.g., a transceiver IC die). Using one or more spacer dies in place of unused IC dies in an IC package also eliminates the need to redesign the IC package to house a reduced number of IC dies. Thus, the spacer dies can substantially reduce the cost and the development time associated with implementing different applications for an IC package that use a different number of IC dies in the IC package. The spacer dies also eliminate the need to build custom-made IC packages for unique applications that may be over-built, reduce the time to develop and test IC packages that can be used for many different applications, and reduce the risk of a disruption to the timing of the development of IC packages for different applications. In addition, using one or more spacer dies in place of one or more unused IC dies in an IC package allows a single IC package design to be used with IC dies that are currently available, without being dependent on the development and testing of the IC dies that are unavailable and/or have a longer testing and development cycle.

One or more specific examples are described below. In an effort to provide a concise description of these examples, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Throughout the specification, and in the claims, the term “connected” means a direct electrical connection between the circuits that are connected, without any intermediary devices. The term “coupled” means either a direct electrical connection between circuits or an indirect electrical connection through one or more passive or active intermediary devices that allows the transfer of information between circuits. The term “circuit” may mean one or more passive and/or active electrical components that are arranged to cooperate with one another to provide a desired function.

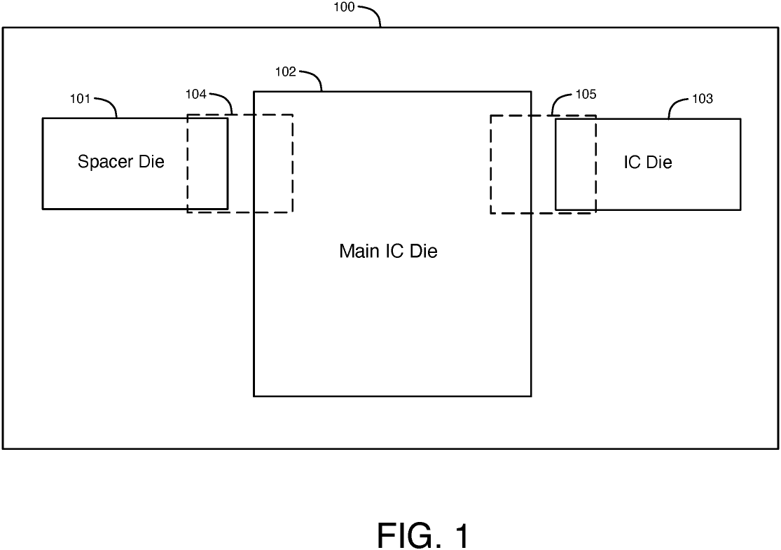

FIG. 1 is a diagram that illustrates a top down view of an example of an integrated circuit (IC) package that includes a package substrate 100, a spacer die 101, a main integrated circuit (IC) die 102, and an additional IC die 103. The IC package of FIG. 1 also includes two interconnection bridges 104-105 that are embedded in the package substrate 100. The IC package of FIG. 1 is designed to be used with up to three integrated circuit (IC) dies. As shown in FIG. 1, the third IC die is replaced with the spacer die 101, because the third IC die is not used in the application of the IC package of FIG. 1. The spacer die 101 can be the same size (and have the same footprint and dimensions) as the third IC die that is replaced. The spacer die 101 is an open circuit die (e.g., a die made only of semiconductor material such as silicon) that does not include active circuits (e.g., transistors) and does not include passive circuits (e.g., resistors or capacitors). The spacer die 101 can be, for example, an open circuit short-loop die made from a semiconductor wafer. A short loop die is made from a wafer that is run through only a subset of the process steps used to create an IC die, such as IC dies 102-103.

The location of the spacer die 101 shown in FIG. 1 is merely one example. In other examples, a spacer die can be placed in any location in the IC package as a replacement for an IC die. If, for example, the IC die 103 is replaced with a spacer die, then the spacer die 101 can be replaced with an IC die containing active circuitry, or the spacer die 101 can remain in the IC package at the location shown in FIG. 1. Thus, using one or more spacer dies provides the flexibility to allow the IC package of FIG. 1 to be used for different applications that use different numbers of IC dies (e.g., 1, 2, or 3 IC dies).

The main IC die 102 can be any type of IC die, such as a processing integrated circuit (IC) (e.g., a programmable logic IC, a microprocessor IC, or a graphics processing unit IC), a memory IC, an application specific IC, etc. The second IC die 103 in the IC package of FIG. 1 can also be any type of IC die, such as a transceiver IC that implements a data transmission protocol with one or more external devices, a memory IC, an application specific IC, a processing IC, etc.

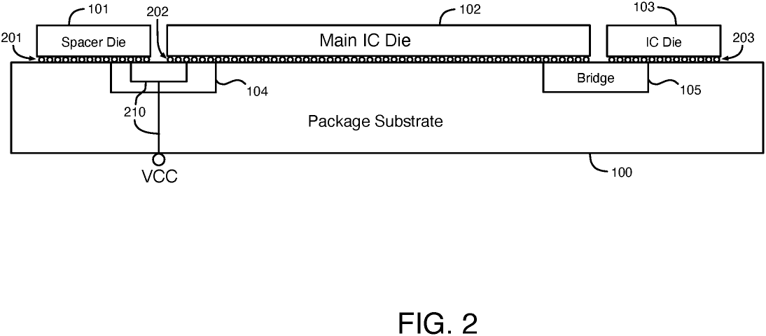

FIG. 2 is a diagram that illustrates a cross sectional view of the integrated circuit (IC) package of FIG. 1. As shown in FIG. 2, the IC package includes conductive bumps 201, 202, and 203 that couple the spacer die 101, the main IC die 102, and the additional IC die 103, respectively, to conductors in the package substrate 100. Each of the package substrate 100, interconnection bridge 104, and interconnection bridge 105 includes conductors (e.g., conductive traces and vias) that are not shown in FIG. 2. In addition, the spacer die 101 and the main IC die 102 are coupled to the interconnection bridge 104 through subsets of the conductive bumps 201-202, respectively. The main IC die 102 and the additional IC die 103 are coupled to the interconnection bridge 105 through subsets of the conductive bumps 202-203, respectively.

Because the spacer die 101 is an open circuit die that does not include active or passive circuits, the spacer die 101 blocks any leakage current through the spacer die 101 between the package substrate 100/interconnection bridge 104 and any package material above the spacer die 101 (such as a thermal interface material). Therefore, the spacer die 101 adds no additional power consumption to the IC package of FIGS. 1-2. In addition, because the spacer die 101 does not include any conductive paths, the spacer die 101 cannot create a short between the conductive bumps 201 and any package material above the spacer die 101 (such as a thermal interface material). Also, the spacer die 101 can have the same (or similar) thermal characteristics as the third IC die that the spacer die 101 replaces. For example, the spacer die 101 can provide effective heat dissipation in the IC package of FIGS. 1-2 between the thermal interface material (not shown) and the package substrate 100.

FIG. 2 illustrates conductors 210 in the package substrate 100 and in the interconnection bridge 104 that provide a supply voltage VCC to each of the main IC die 102 and the spacer die 101. In order to avoid the possibility that a short of the supply voltage VCC will cause damage to the circuitry in the main IC die 102, the spacer die 101 can be selected to be a short loop die with all open circuits. The IC package of FIGS. 1-2 can have electro-static discharge (ESD) protection circuitry in one or both of the IC dies 102-103 that is not dependent on the spacer die 101 having ESD protection circuitry.

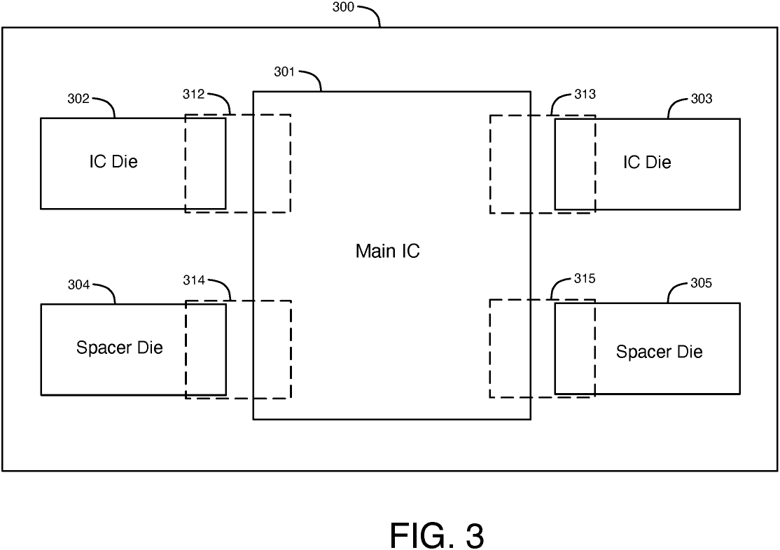

FIG. 3 is a diagram that illustrates a top down view of an example of an integrated circuit (IC) package that includes a package substrate 300, a main integrated circuit (IC) die 301, two additional IC dies 302-303, and two spacer dies 304-305. The IC package of FIG. 3 also includes 4 interconnection bridges 312-315 that are embedded in the package substrate 300. The IC package of FIG. 3 is designed to be used with up to 5 integrated circuit dies. As shown in FIG. 3, the fourth and fifth IC dies are replaced with spacer dies 304-305, because the fourth and fifth IC dies are not used in the application of the IC package shown in the example of FIG. 3. The spacer dies 304-305 can be the same sizes (and have the same footprints and dimensions) as the fourth and fifth IC dies that are replaced. Each of the spacer dies 304-305 is an open circuit die (e.g., a die made only of semiconductor material such as silicon) that does not include active circuits and does not include passive circuits.

The locations of the spacer dies 304-305 are shown in FIG. 3 merely as examples. In other examples, one or more spacer dies can be provided in any locations in the IC package of FIG. 3, for example, as a replacement for one or more of the IC dies 302-303. According to variations of the IC package shown in FIG. 3 for different applications, the IC package can include 1, 2, 3, or 4 IC dies with active circuitry in any one or more of the locations shown by reference numerals 302-305 in FIG. 3, and the IC package can include 1, 2, 3, or 4 spacer dies in any one or more of the locations shown by reference numerals 302-305 in FIG. 3 that replace one or more IC dies. Thus, using one or more spacer dies provides the flexibility to allow the IC package of FIG. 3 to be used for different applications that use different numbers of IC dies (e.g., 1, 2, 3, 4, or 5 IC dies).

Because the spacer dies 304-305 are open circuit dies that do not include active or passive circuits, the spacer dies 304-305 block any leakage current through the spacer dies between the package substrate 300 (e.g., interconnection bridges 314-315) and any package material above the spacer dies (such as a thermal interface material). Therefore, the spacer dies 304-305 add no additional power consumption to the IC package of FIG. 3. In addition, because the spacer dies 304-305 do not include any conductive paths, the spacer dies 304-305 cannot create shorts between any package material above the spacer dies and the package substrate 300. Also, the spacer dies 304-305 can have the same (or similar) thermal characteristics as the IC dies that the spacer dies replace. For example, the spacer dies 304-305 can provide effective heat dissipation in the IC package between the thermal interface material (not shown) and the package substrate 300.

The package substrate 300 and each of the interconnection bridges 312-215 includes conductors (e.g., conductive traces and vias) that are not shown in FIG. 3. The main IC die 301 is coupled to the additional IC die 302 through conductors in the interconnection bridge 312. The main IC die 301 is coupled to the additional IC die 303 through conductors in the interconnection bridge 313. The spacer die 304 and the main IC die 301 are coupled to interconnection bridge 314. The spacer die 305 and the main IC die 301 are coupled to the interconnection bridge 315. If either of the spacer dies 304 or 305 is replaced with an additional IC die, the main IC die 301 can be coupled to the additional IC die through conductors in the respective interconnection bridge 314 or 315.

The main IC die 301 can be any type of IC die, such as a microprocessor IC die, a programmable logic IC die (e.g., a field programmable gate array), a graphics processing unit (GPU) IC die, a memory IC die, an application specific IC die, etc. The other IC dies 302-303 in the IC package of FIG. 3 can also be any types of IC dies, such as transceiver IC dies that implement data transmission protocols with one or more external devices and the main IC die 301, memory IC dies, application specific IC dies, microprocessor IC dies, etc. The IC dies 302-303 can be the same type of IC die or different types of IC dies.

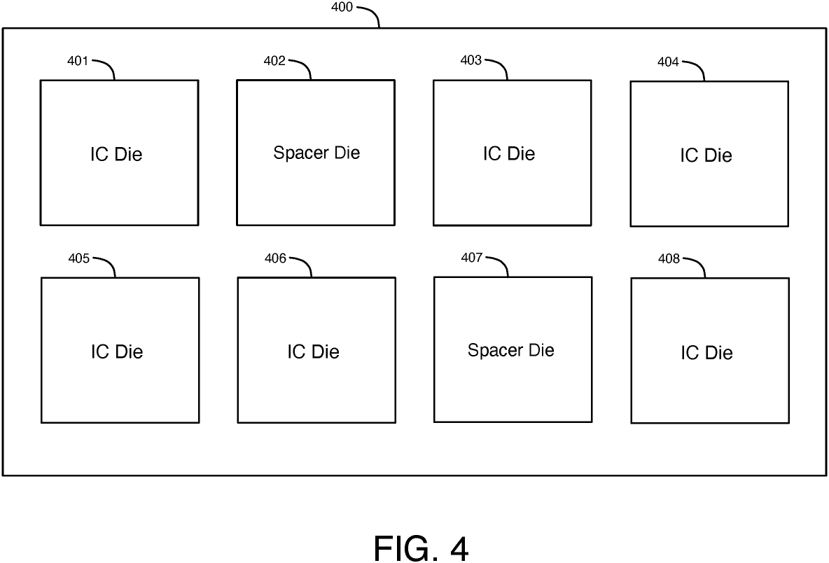

FIG. 4 is a diagram that illustrates a top down view of an example of an integrated circuit (IC) package that includes a package substrate 400, 6 IC dies that contain active circuitry, and two spacer dies. The IC package of FIG. 4 is designed to be used with up to 8 integrated circuit dies, but the IC package of FIG. 4 only includes 6 integrated circuit (IC) dies 401, 403-406, and 408 that have active circuitry and that are coupled to package substrate 400. In the example of FIG. 4, two of the 8 possible IC dies are replaced with spacer dies 402 and 407, because the two IC dies are not used in the application of the IC package shown in the example of FIG. 4. The spacer dies 402 and 407 are coupled to the package substrate 400. The spacer dies 402 and 407 can be the same sizes (and have the same footprints) as the two IC dies that are replaced. Each of the spacer dies 402 and 407 is an open circuit die (e.g., a die made only of semiconductor material such as silicon) that does not include active circuits and does not include passive circuits, as with the previous examples. The IC dies in the IC package of FIG. 4 can be any types of IC dies, such as microprocessor IC dies (e.g., central processing units), programmable logic IC dies (e.g., field programmable gate arrays), graphics processing unit (GPU) IC dies, memory IC dies, application specific IC dies, etc. The IC dies in the IC package of FIG. 4 can be the same type of IC die or different types of IC dies. In an alternative example, package substrate 400 can be replaced with an interposer coupled to the IC dies and the spacer dies.

The locations of the spacer dies 402 and 407 shown in FIG. 4 are merely examples. In other examples, one or more spacer dies can be provided in any location in the IC package of FIG. 4, for example, as a replacement for one or more of the IC dies 401, 403-406, and/or 408. According to variations of the IC package shown in FIG. 4 for different applications, the IC package can include 1, 2, 3, 4, 5, 6, 7, or 8 IC dies with active circuitry in any one or more of the locations shown by reference numerals 401-408 in FIG. 4, and the IC package can include 1, 2, 3, 4, 5, 6, or 7 spacer dies in any one or more of the locations shown by reference numerals 401-408 in FIG. 4 that replace one or more IC dies. Thus, using one or more spacer dies provides the flexibility to allow the IC package of FIG. 4 to be used for different applications that use different numbers of IC dies.

Because the spacer dies 402 and 407 are open circuit dies that do not include active or passive circuits, the spacer dies 402 and 407 block any leakage current through the spacer dies between the package substrate 400 and any package material above the spacer dies (such as a thermal interface material). Therefore, the spacer dies 402 and 407 add no additional power consumption to the IC package of FIG. 4. In addition, because the spacer dies 402 and 407 do not include any conductive paths, the spacer dies 402 and 407 cannot create shorts between any package material above the spacer dies and the package substrate 400. Also, the spacer dies 402 and 407 can have the same (or similar) thermal characteristics as the IC dies that the spacer dies replace. For example, the spacer dies 402 and 407 can provide effective heat dissipation in the IC package between the thermal interface material (not shown) and the package substrate 400.

The spacer dies and the IC packages disclosed herein, for example with respect to FIGS. 1-4, do not require additional research and development time and cost to design and test for quality. The spacer dies typically cost substantially less than IC dies that include active circuits. A single IC package design can be used (and reused) for multiple different applications by adding one or more spacer dies in the IC package in place of one or more unused IC dies. As a result, the IC package does not need to be resigned to house a reduced number of IC dies, and the IC package can be available to implement applications with varying numbers of IC dies. Therefore, the spacer dies disclosed herein, for example with respect to FIGS. 1-4, can substantially reduce the cost and the development time associated with implementing different applications for an IC package that use different numbers of IC dies.

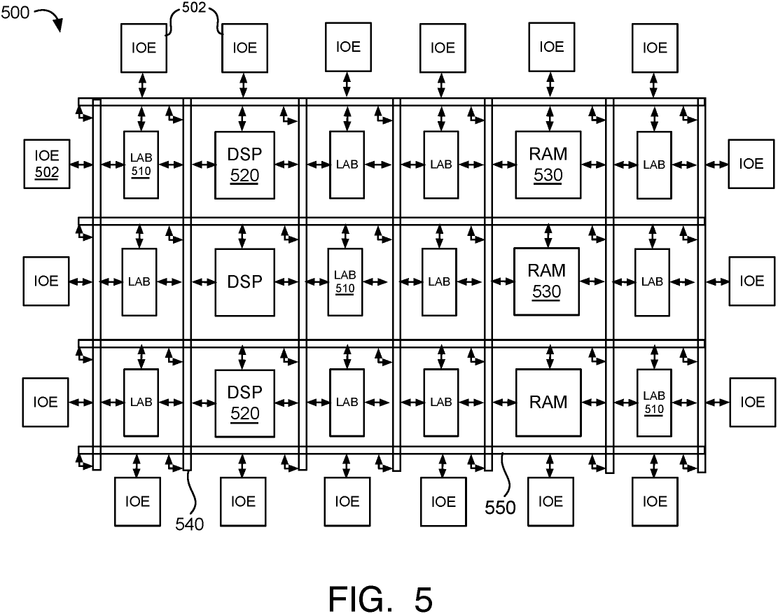

FIG. 5 illustrates an example of a programmable logic integrated circuit (IC) 500 that can be, for example, the main IC die 102 disclosed herein with respect to FIGS. 1-2, the main IC die 301 disclosed herein with respect to FIG. 3, and/or any one or more of the IC dies used in the IC package of FIG. 4 (in any of locations 401-408). As shown in FIG. 5, the programmable logic integrated circuit (IC) 500 includes a two-dimensional array of configurable functional circuit blocks, including configurable logic array blocks (LABs) 510 and other functional circuit blocks, such as random access memory (RAM) blocks 530 and digital signal processing (DSP) blocks 520. Functional blocks such as LABs 510 can include smaller programmable logic circuits (e.g., logic elements, logic blocks, or adaptive logic modules) that receive input signals and perform custom functions on the input signals to produce output signals.

In addition, programmable logic IC 500 can have input/output elements (IOEs) 502 for driving signals off of programmable logic IC 500 and for receiving signals from other devices. Input/output elements 502 can include parallel input/output circuitry, serial data transceiver circuitry, differential receiver and transmitter circuitry, or other circuitry used to connect one integrated circuit to another integrated circuit. As shown, input/output elements 502 can be located around the periphery of the chip. If desired, the programmable logic IC 500 can have input/output elements 502 arranged in different ways. For example, input/output elements 502 can form one or more columns, rows, or islands of input/output elements that may be located anywhere on the programmable logic IC 500.

The programmable logic IC 500 can also include programmable interconnect circuitry in the form of vertical routing channels 540 (i.e., interconnects formed along a vertical axis of programmable logic IC 500) and horizontal routing channels 550 (i.e., interconnects formed along a horizontal axis of programmable logic IC 500), each routing channel including at least one conductor to route at least one signal.

Note that other routing topologies, besides the topology of the interconnect circuitry depicted in FIG. 5, may be used. For example, the routing topology can include wires that travel diagonally or that travel horizontally and vertically along different parts of their extent as well as wires that are perpendicular to the device plane in the case of three dimensional integrated circuits. The driver of a wire can be located at a different point than one end of a wire.

Furthermore, it should be understood that embodiments disclosed herein with respect to FIGS. 1-4 can be implemented in any integrated circuit or electronic system. If desired, the functional blocks of such an integrated circuit can be arranged in more levels or layers in which multiple functional blocks are interconnected to form still larger blocks. Other device arrangements can use functional blocks that are not arranged in rows and columns.

Programmable logic IC 500 can contain programmable memory elements. Memory elements can be loaded with configuration data using input/output elements (IOEs) 502. Once loaded, the memory elements each provide a corresponding static control signal that controls the operation of an associated configurable functional block (e.g., LABs 510, DSP blocks 520, RAM blocks 530, or input/output elements 502).

In a typical scenario, the outputs of the loaded memory elements are applied to the gates of metal-oxide-semiconductor field-effect transistors (MOSFETs) in a functional block to turn certain transistors on or off and thereby configure the logic in the functional block including the routing paths. Programmable logic circuit elements that can be controlled in this way include multiplexers (e.g., multiplexers used for forming routing paths in interconnect circuits), look-up tables, logic arrays, AND, OR, XOR, NAND, and NOR logic gates, pass gates, etc.

The programmable memory elements can be organized in a configuration memory array having rows and columns. A data register that spans across all columns and an address register that spans across all rows can receive configuration data. The configuration data can be shifted onto the data register. When the appropriate address register is asserted, the data register writes the configuration data to the configuration memory bits of the row that was designated by the address register.

In certain embodiments, programmable logic IC 500 can include configuration memory that is organized in sectors, whereby a sector can include the configuration RAM bits that specify the functions and/or interconnections of the subcomponents and wires in or crossing that sector. Each sector can include separate data and address registers.

The programmable logic IC of FIG. 5 is merely one example of an IC that can be used with embodiments disclosed herein. The embodiments disclosed herein can be used with any suitable integrated circuit or system. For example, the embodiments disclosed herein can be used with numerous types of devices such as processor integrated circuits, central processing units, memory integrated circuits, graphics processing unit integrated circuits, application specific standard products (ASSPs), application specific integrated circuits (ASICs), and programmable logic integrated circuits. Examples of programmable logic integrated circuits include programmable arrays logic (PALs), programmable logic arrays (PLAs), field programmable logic arrays (FPLAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The integrated circuits disclosed in one or more embodiments herein can be part of a data processing system that includes one or more of the following components: a processor; memory; input/output circuitry; and peripheral devices. The data processing system can be used in a wide variety of applications, such as computer networking, data networking, instrumentation, video processing, digital signal processing, or any suitable other application. The integrated circuits can be used to perform a variety of different logic functions.

In general, software and data for performing any of the functions disclosed herein can be stored in non-transitory computer readable storage media. Non-transitory computer readable storage media is tangible computer readable storage media that stores data and software for access at a later time, as opposed to media that only transmits propagating electrical signals (e.g., wires). The software code may sometimes be referred to as software, data, program instructions, instructions, or code. The non-transitory computer readable storage media can, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

Additional examples are now described. Example 1 is an integrated circuit package comprising: a first integrated circuit die; and a first spacer die coupled in the integrated circuit package in a first location designed to house a second integrated circuit die.

In Example 2, the integrated circuit package of Example 1 further comprises: a package substrate coupled to the first integrated circuit die and to the first spacer die.

In Example 3, the integrated circuit package of any one of Examples 1-2 further comprises: a second spacer die coupled in the integrated circuit package in a second location designed to house a third integrated circuit die.

In Example 4, the integrated circuit package of any one of Examples 1-3, wherein the first spacer die is an open circuit die that blocks leakage current.

In Example 5, the integrated circuit package of any one of Examples 1-4, wherein the first integrated circuit die comprises a processing integrated circuit.

In Example 6, the integrated circuit package of any one of Examples 1-5 further comprises: a third integrated circuit die coupled to the first integrated circuit die.

In Example 7, the integrated circuit package of Example 6, wherein the third integrated circuit die comprises a first transceiver integrated circuit, and wherein the first spacer die is coupled in the integrated circuit package in the first location that is designed to house a second transceiver integrated circuit.

In Example 8, the integrated circuit package of any one of Examples 1-7, wherein the first spacer die has a same size as the second integrated circuit die.

Example 9 is a method for forming an integrated circuit package, the method comprising: coupling a first integrated circuit die in the integrated circuit package; and coupling a first spacer die in the integrated circuit package in a first location designed to house a second integrated circuit die.

In Example 10, the method of Example 9, wherein coupling the first integrated circuit die in the integrated circuit package and coupling the first spacer die in the integrated circuit package further comprise coupling the first integrated circuit die and the first spacer die to a package substrate.

In Example 11, the method of any one of Examples 9-10 further comprises: coupling a second spacer die in the integrated circuit package in a second location designed to house a third integrated circuit die.

In Example 12, the method of Example 11, wherein each of the first and the second spacer dies is an open circuit die that lacks active circuits.

In Example 13, the method of any one of Examples 9-12 further comprises: coupling a third integrated circuit die to the first integrated circuit die in the integrated circuit package.

In Example 14, the method of any one of Examples 9-13, wherein the first integrated circuit die comprises a processing integrated circuit, and wherein the first spacer die is coupled in the integrated circuit package in the first location that is designed to house a transceiver integrated circuit.

Example 15 is a circuit system comprising: a substrate; a first integrated circuit die coupled to the substrate; and a first spacer die coupled to the substrate at a first location designed to house a second integrated circuit die.

In Example 16, the circuit system of Example 15 further comprises: a second spacer die coupled to the substrate at a second location designed to house a third integrated circuit die.

In Example 17, the circuit system of any one of Examples 15-16, wherein the substrate is a package substrate, and wherein the circuit system is an integrated circuit package.

In Example 18, the circuit system of any one of Examples 15-17 further comprises: a third integrated circuit die coupled to the substrate.

In Example 19, the circuit system of any one of Examples 15-18, wherein the first spacer die is an open circuit die that blocks leakage current through the first spacer die.

In Example 20, the circuit system of any one of Examples 15-19, wherein the first spacer die has a same footprint over the substrate as the second integrated circuit die.

The foregoing description of the examples has been presented for the purpose of illustration. The foregoing description is not intended to be exhaustive or to be limiting to the examples disclosed herein. In some instances, features of the examples can be employed without a corresponding use of other features as set forth. Many modifications, substitutions, and variations are possible in light of the above teachings.

What is claimed is:

1. An integrated circuit package comprising:
a first integrated circuit die; and
a first spacer die coupled in the integrated circuit package in a first location designed to house a second integrated circuit die.

2. The integrated circuit package of claim 1 further comprising:
a package substrate coupled to the first integrated circuit die and to the first spacer die.

3. The integrated circuit package of claim 1 further comprising:
a second spacer die coupled in the integrated circuit package in a second location designed to house a third integrated circuit die.

4. The integrated circuit package of claim 1, wherein the first spacer die is an open circuit die that blocks leakage current.

5. The integrated circuit package of claim 1, wherein the first integrated circuit die comprises a processing integrated circuit.

6. The integrated circuit package of claim 1 further comprising:
a third integrated circuit die coupled to the first integrated circuit die.

7. The integrated circuit package of claim 6, wherein the third integrated circuit die comprises a first transceiver integrated circuit, and wherein the first spacer die is coupled in the integrated circuit package in the first location that is designed to house a second transceiver integrated circuit.

8. The integrated circuit package of claim 1, wherein the first spacer die has a same size as the second integrated circuit die.

9. A method for forming an integrated circuit package, the method comprising:
coupling a first integrated circuit die in the integrated circuit package; and
coupling a first spacer die in the integrated circuit package in a first location designed to house a second integrated circuit die.

10. The method of claim 9, wherein coupling the first integrated circuit die in the integrated circuit package and coupling the first spacer die in the integrated circuit package further comprise coupling the first integrated circuit die and the first spacer die to a package substrate.

11. The method of claim 9 further comprising:
coupling a second spacer die in the integrated circuit package in a second location designed to house a third integrated circuit die.

12. The method of claim 11, wherein each of the first and the second spacer dies is an open circuit die that lacks active circuits.

13. The method of claim 9 further comprising:
coupling a third integrated circuit die to the first integrated circuit die in the integrated circuit package.

14. The method of claim 9, wherein the first integrated circuit die comprises a processing integrated circuit, and wherein the first spacer die is coupled in the integrated circuit package in the first location that is designed to house a transceiver integrated circuit.

15. A circuit system comprising:
a substrate;
a first integrated circuit die coupled to the substrate; and
a first spacer die coupled to the substrate at a first location designed to house a second integrated circuit die.

16. The circuit system of claim 15 further comprising:
a second spacer die coupled to the substrate at a second location designed to house a third integrated circuit die.

17. The circuit system of claim 15, wherein the substrate is a package substrate, and wherein the circuit system is an integrated circuit package.

18. The circuit system of claim 15 further comprising:
a third integrated circuit die coupled to the substrate.

19. The circuit system of claim 15, wherein the first spacer die is an open circuit die that blocks leakage current through the first spacer die.

20. The circuit system of claim 15, wherein the first spacer die has a same footprint over the substrate as the second integrated circuit die.
